(19) United States
(12) Patent Application Publication
(10) Pub. No.: US 2013/0203229 A1
(43) Pub. Date: Aug. 8, 2013

(54) METHOD OF REDUCING SURFACE DOPING CONCENTRATION OF DOPED DIFFUSION REGION, METHOD OF MANUFACTURING SUPER JUNCTION USING THE SAME AND METHOD OF MANUFACTURING POWER TRANSISTOR DEVICE

(71) Applicants: Yung-Fa Lin, Hsinchu City (TW); Shou-Yi Hsu, Hsinchu County (TW); Meng-Wei Wu, Hsinchu City (TW); Chia-Hao Chang, Hsinchu City (TW)

(72) Inventors: Yung-Fa Lin, Hsinchu City (TW); Shou-Yi Hsu, Hsinchu County (TW); Meng-Wei Wu, Hsinchu City (TW); Chia-Hao Chang, Hsinchu City (TW)

(21) Appl. No.: 13/537,080

(22) Filed: Jun. 29, 2012

(30) Foreign Application Priority Data
Feb. 2, 2012 (TW) 101103343

(51) Int. Cl. H01L 21/336; H01L 21/322

(52) U.S. Cl. 438/268; 438/511; 257/E21.317; 257/E21.41

(57) ABSTRACT

The present invention provides a method of reducing a surface doping concentration of a doped diffusion region. First, a semiconductor substrate is provided. The semiconductor substrate has the doped diffusion region disposed therein, and the doped diffusion region is in contact with a surface of the semiconductor substrate. A doping concentration of the doped diffusion region close to the surface is larger than a doping concentration of the doped diffusion region away from the surface. Then, a thermal oxidation process is performed to form an oxide layer on the surface of the semiconductor substrate. A part of the doped diffusion region in contact with the surface reacts with oxygen to form a part of the oxide layer. Then, the oxide layer is removed.

### BACKGROUND OF THE INVENTION

1. Field of the Invention

The present invention generally relates to a method of reducing a surface doping concentration of a doped diffusion region, a method of manufacturing a super junction structure and a method of manufacturing a power transistor device.

2. Description of the Prior Art

In a power transistor device, power consumption is directly proportional to on resistance (RDS(on)) between drain and source of the device, and thus the power consumption of the power transistor device can be reduced by decreasing the on resistance. Resistance generated from an epitaxial layer used for withstanding high voltage occupies the largest percentage of the on resistance. The resistance of the epitaxial layer can be decreased by increasing the doping concentration of the dopant therein; however, the epitaxial layer is used to tolerate high voltage, and the breakdown voltage of the epitaxial layer is reduced when the doping concentration is increased, so that ability to tolerate the high voltage of power transistor devices is reduced.

In order to overcome these drawbacks, a kind of power transistor device having a super junction structure is developed to have both high voltage sustaining ability and low on resistance. In a conventional method for fabricating a power transistor device, an N-type epitaxial layer is formed on an N-type substrate. Then, a plurality of deep trenches is etched into the N-type epitaxial layer. A dopant source layer is filled into each deep trench followed by performing a high-temperature diffusion process. In this way, P-type dopants inside the dopant source layer can diffuse into the N-type epitaxial layer and a plurality of P-type doped regions can be formed. A structure including PN junctions (alternately arranged N-type epitaxial layer and the P-type doped regions in this case) vertical to the substrate is also called a super junction structure. However, since the P-type doped regions are formed by diffusion process, the closer to the sidewall of each deep trench the P-type doped region is, the higher the doping concentration of the P-type doped region is. As a result, a surface doping concentration in each P-type doped region tends to be too high, which causes the concentration distribution of hole carriers and the concentration distribution of electron carriers in the super junction structure to be non-uniform. Therefore, a voltage sustaining ability of the super junction structure is reduced.

In light of the above, there is a need to reduce a surface doping concentration of each P-type doped region in order to solve the problems about non-uniform concentration distribution of the hole carriers and the electron carriers in a super junction structure.

### SUMMARY OF THE INVENTION

It is therefore an objective of the present invention to provide a method of reducing a surface doping concentration of a doped diffusion region, a method of manufacturing a super junction structure and method of manufacturing a power transistor device in order to solve the above-mentioned problems.

To this end, according to an embodiment of the present invention, a method of manufacturing a super junction structure is disclosed. First, a semiconductor substrate having a first conductivity type is provided. Then, at least a trench is formed in the semiconductor substrate. Two doped diffusion regions are separately formed in the semiconductor substrate on two sides of the trench, wherein a doping concentration of each of the doped diffusion regions close to a sidewall of the trench is larger than a doping concentration of each of the doped diffusion regions away from the sidewall of the trench, and each of the doped diffusion regions has a second conductivity type different from the first conductivity type. Then, a thermal oxidation process is performed to form an oxide layer on the sidewall of the trench, wherein a part of each of the doped diffusion regions in contact with the sidewall of the trench is reacted with oxygen to form a part of the oxide layer. Finally, the oxide layer is removed.

According to another embodiment, the present invention provides a method for manufacturing a power transistor device which includes the following steps. First, a semiconductor substrate having a first conductivity type is provided. Then, at least a trench is formed in the semiconductor substrate. Two doped diffusion regions are separately formed in the semiconductor substrate on both sides of the trench, wherein a doping concentration of each of the doped diffusion regions close to a sidewall of the trench is larger than a doping concentration of each of the doped diffusion regions away from the sidewall of the trench, and each of the doped diffusion regions has a second conductivity type different from the first conductivity type. A thermal oxidation process is performed to form an oxide layer on the sidewall of the trench, wherein a part of each of the doped diffusion regions in contact with the sidewall of the trench reacts with oxygen to form a part of the oxide layer. Then, the oxide layer is removed and an insulating layer is formed in the trench. Subsequently, a gate structure is formed on the semiconductor substrate on at least the side of the trench and two doped base regions are separately formed in the semiconductor substrate on both sides of the gate structure, and each of the doped base regions is respectively in contact with each of the doped diffusion regions, wherein the doped base regions have the second conductivity type. Finally, a doped source region is formed in the respective doped base region.

According to still another embodiment, the present invention provides a method for reducing a surface doping concentration of a doped diffusion region. First, a semiconductor substrate having a doped diffusion region disposed therein is provided, and the doped diffusion region is in contact with a surface of the semiconductor substrate, wherein a doping concentration of the doped diffusion region close to the surface is larger than a doping concentration of the doped diffusion region away from the surface. Then, a thermal oxidation process is carried out to form an oxide layer on the surface of the semiconductor substrate, wherein a part of the doped diffusion region in contact with the surface is reacted with oxygen to form a part of the oxide layer. Subsequently, the oxide layer is removed.

The present invention provides a thermal oxidation process to let a portion of each doped diffusion region adjacent to each trench can be oxidized into an oxide layer. Since the oxide layer is oxidized from the doped diffusion region with a relatively high doping concentration, if the oxide layer is removed through a suitable removing process, a surface doping concentration of the doped diffusion region can therefore be reduced effectively. As a result, a much uniform carrier distribution can be obtained in the super junction structure and a voltage sustaining ability of the super junction structure is hence improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 3 are schematic, cross-sectional diagrams illustrating a method of reducing a surface doping concentration of a doped diffusion region according one embodiment of the present invention.

FIGS. 4 to 13 are schematic, cross-sectional diagrams illustrating a method of manufacturing a power transistor device according to one embodiment of the present invention.

FIGS. 14 to 15 are schematic, cross-sectional diagrams illustrating a method of manufacturing a super junction structure according to another embodiment of the present invention.

### DETAILED DESCRIPTION

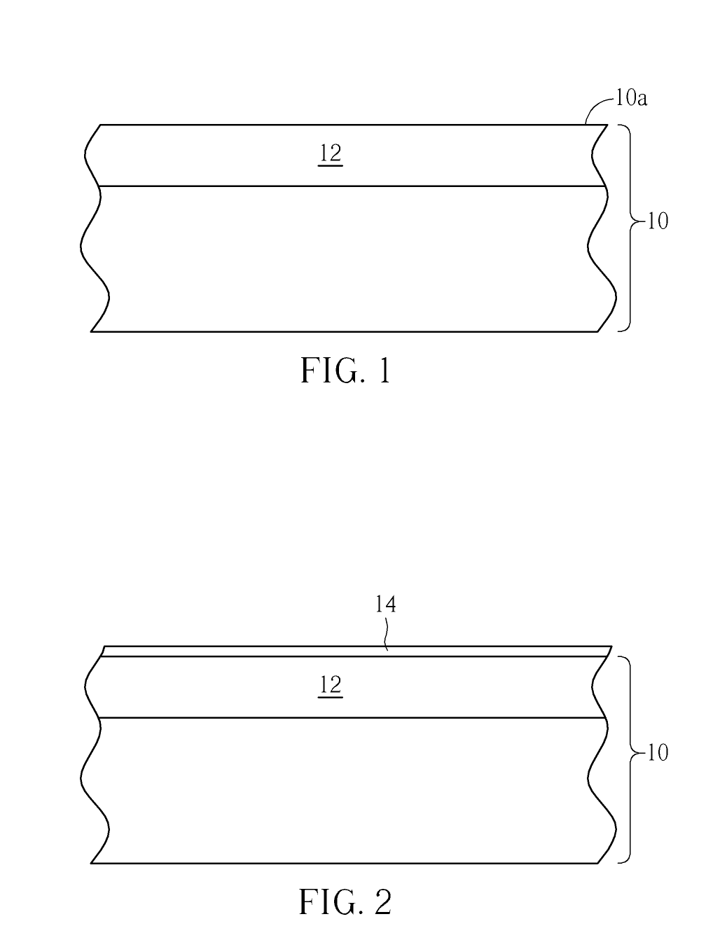

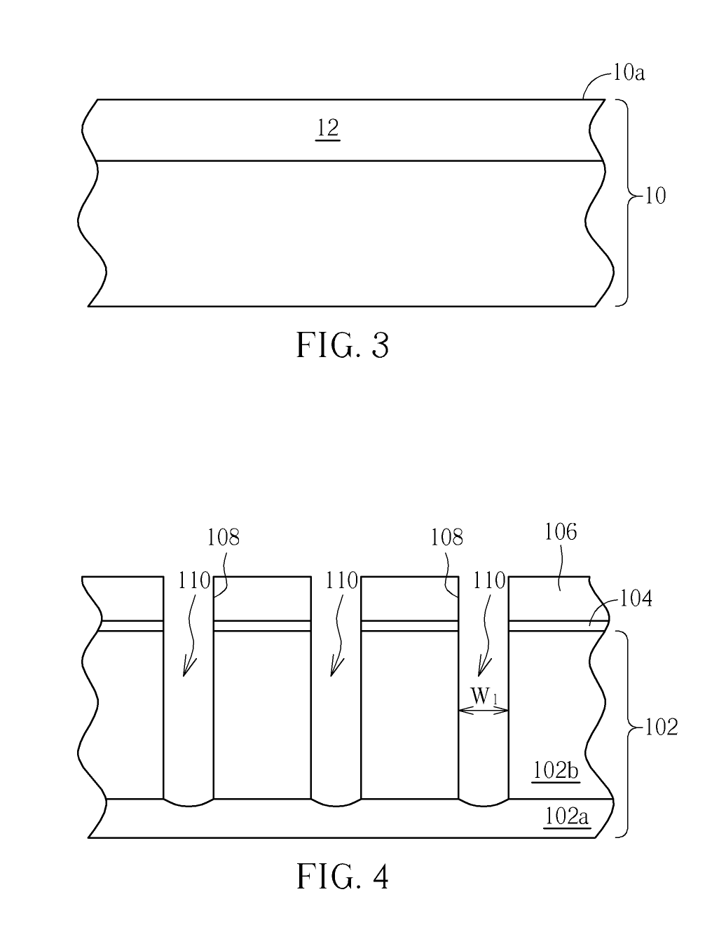

Please refer to FIGS. 1 to 3. FIGS. 1 to 3 are schematic, cross-sectional diagrams illustrating a method of reducing a surface doping concentration of a doped diffusion region according one embodiment of the present invention. As shown in FIG. 1, a semiconductor substrate 10 having a first conductivity type, such as silicon wafer, is provided. A doped diffusion region 12 is disposed in the semiconductor substrate 10 and in contact with an upper surface 10a of the semiconductor substrate 10. A doping concentration of the doped diffusion region 12 close to the upper surface 10a is higher than that of the doped diffusion region 12 away from the upper surface 10a. As shown in FIG. 2, a thermal oxidation process is performed to form an oxide layer 14 on the upper surface 10a of the semiconductor substrate 10. It is this thermal oxidation process that a portion of the doped diffusion region 12 with relatively high doping concentration close to the upper surface 10a can react with oxygen to form the oxide layer 14. As shown in FIG. 3, the oxide layer 14 that is formed by oxidizing the portion of the doped diffusion region 12 with relatively high doping concentration is then removed. Accordingly, a surface doping concentration of the doped diffusion region can therefore be reduced effectively. In this embodiment, conductivity types of the doped diffusion region 12 and the semiconductor substrate 10 may be N-type or P-type, and the conductivity type of the doped diffusion region 12 may be the same with or different from that of the semiconductor substrate 10.

Furthermore, the method for reducing the surface doping concentration of the doped diffusion regions can also be applied to a method for fabricating a super junction structure in a power transistor device. In this way, a much reduced and more uniform carrier distribution can be obtained in the super junction structure. However, the method of reducing the surface doping concentration of the doped diffusion regions is not limited applications in this field; it can also be properly applied to other suitable fields. Please refer to FIGS. 4 to 13, which are schematic, cross-sectional diagrams illustrating a method of manufacturing a power transistor device according to one embodiment of the present invention. Furthermore, diagrams depicted in FIGS. 4 to 7 show a method of manufacturing a super junction structure according to embodiments of the present invention. As shown in FIG. 4, a semiconductor substrate 102 having a first conductivity type is provided. A pad layer 104, silicon oxide (SiO₂) for example, but not limited thereto, is then formed on the semiconductor substrate 102. A hard mask layer 106, such as silicon nitride (Si₃N₄), but not limited thereto, is formed on the pad layer 104 through a deposition process. A photolithographic and an etching process are carried out in order to pattern the pad layer 104 and the hard mask layer 106. After this step, a plurality of openings 108, which respectively penetrate the pad layer 104 and the hard mask layer 106, can be formed in the pad layer 104 and the hard mask layer 106, thereby exposing the semiconductor substrate 102. An etching process is carried out by using the hard mask layer 106 as a hard mask to form a plurality of trenches 110 in the semiconductor substrate 102 exposed from the openings 108. At this time, each trench 110 has a first width W₁ approximately equal to a width of each opening 108. In this embodiment, the semiconductor substrate 102 may comprise a base layer 102a, such as silicon wafer, and an epitaxial layer 102b disposed on the base layer 102a. Further, each trench 110 penetrates the epitaxial layer 102b and exposes the base layer 102a. However, in other embodiments, each trench may be chosen not to penetrate the epitaxial layer. Additionally, the number of the openings and the trenches is not limited to more than one, that is to say, there may be only one opening and only one trench in the epitaxial layer.

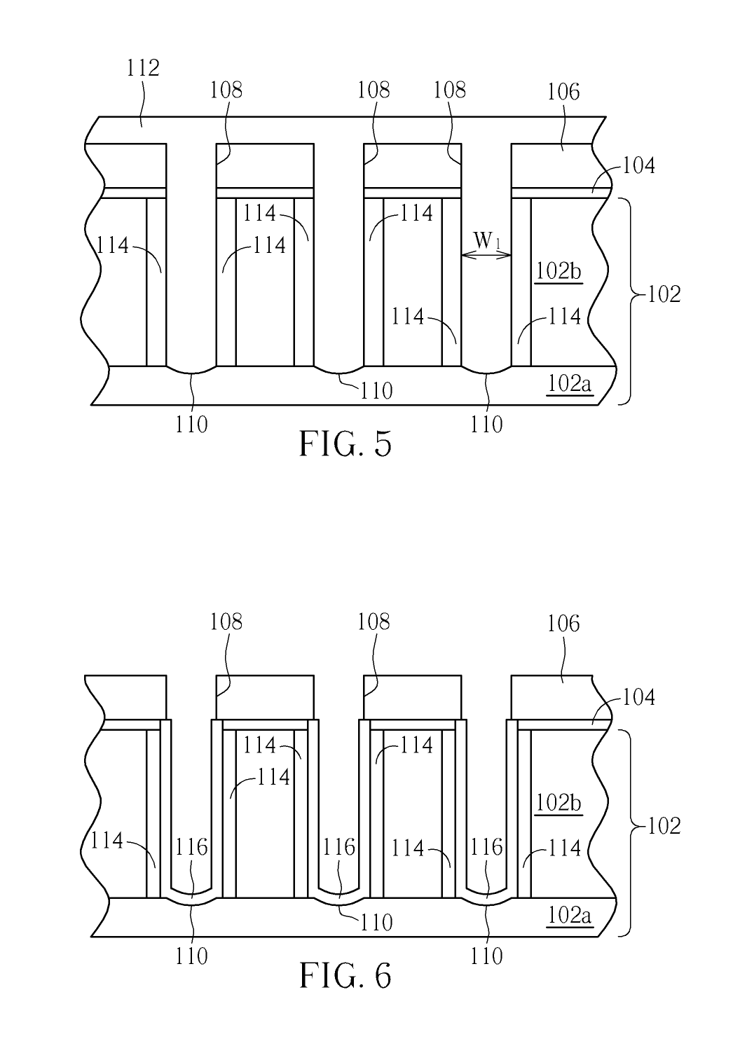

As shown in FIG. 5, a dopant source layer 112 is disposed to cover the surface of the hard mask layer 106 and filled into the trenches 110, wherein the dopant source layer 112 includes a plurality of dopants with a second conductivity type which is different from the first conductivity type. A thermal drive-in process is performed to diffuse the dopants with the second conductivity type into the semiconductor substrate 102 and form two doped diffusion regions 114 in the semiconductor substrate 102 respectively at two sides of each trench 110. Since each doped diffusion region 114 is formed through the thermal diffusion of the dopants, hence, they will also have the second conductivity type. Additionally, when a location of each doped diffusion region 114 is closer to the dopant source layer 112, a doping concentration within each doped diffusion region 114 is higher, that is to say, a doping concentration of each doped diffusion region 114 close to a sidewall of each trench 110 is larger than that of each doped diffusion region 114 away from the sidewall of each trench 110. Preferably, in this embodiment, the first conductivity type is N-type and the second conductivity type is P-type, but is not limited thereto. That is, the first conductivity type and the second conductivity type may be corresponding to P-type and N-type, respectively. The composition of the dopant source layer 112 may be borosilicate glass (BSG), but is not limited thereto. The material of the dopant source layer 112 may be determined by a required conductivity type of doped diffusion regions 114. In other embodiments of the present invention, there may be another way to form a P-type dopant source layer. For example, the method may include performing a P-type ion implantation process to implant P-type dopants into an N-type substrate and then performing a thermal drive-in process to form the P-type dopant source layer, but is not limited thereto.

As shown in FIG. 6, another etching process is carried out to remove the dopant source layer 112. Subsequently, a thermal oxidation process is performed to form an oxide layer 116 on the sidewalls and the bottom of each of the trenches 110. Since each P-type doped diffusion region 114 is formed through a process for doping P-type dopants into the silicon-containing N-type semiconductor substrate 102, each P-type doped diffusion region 114 must include silicon. Additionally, because a portion of each P-type doped diffusion region 114 is in contact with the sidewall of each trench 110 and is exposed from each trench 110, a portion of each P-type doped diffusion region 114 can react with oxygen and form the oxide layer 116. In other words, a part of each P-type doped diffusion region 114 with relatively high doping concentration close to the sidewall of each trench can react with oxygen to form the oxide layer 116. In this embodiment, a thickness of the oxide layer 116 can approximately range from 10 angstroms to 10000 angstroms. And gas applied in the thermal oxidation process may include steam (H₂O), oxygen (O₂), mixed gas of hydrogen chloride (HCl) and steam, mixed gas of hydrogen chloride and oxygen, mixed gas of nitrogen (N₂) and steam, or mixed gas of nitrogen and oxygen at a temperature ranged from 800° C. to 1200° C. Preferably, a pressure of the thermal oxidation process is ranged from 600 Torr to 760 Torr. However, the parameters in the thermal oxidation process are not limited to these.

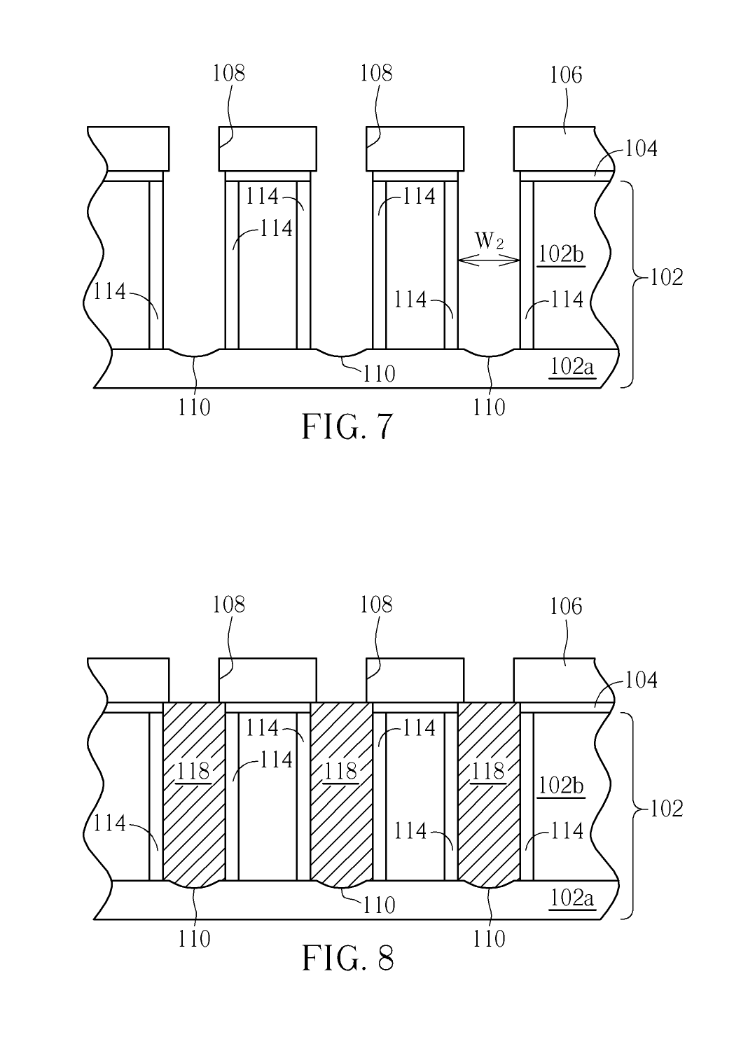

Please refer to FIG. 7, after the above oxidation process, a removing process can be carried out in order to remove the oxide layer 116. Therefore, a portion of each P-type doped diffusion region 114 with relatively high doping concentration, which forms the oxide layer 116 when reacting with oxygen, can be removed during the removing process and a portion of each P-type doped diffusion region 114 with relatively low doping concentration can be exposed from each trench 110. At this time, these alternately arranged P-type doped diffusion regions 114 and the N-type semiconductor substrate 102 can form several PN-junctions approximately vertical to the N-type semiconductor substrate 102, which can build a super junction structure. In this embodiment, the step for removing the oxide layer 116 may include a wet etching process and the oxide layer 116 under the hard mask layer 106 can be removed through the wet etching process, but is not limited thereto. Since a portion of each P-type doped diffusion region 114 is removed by the above-mentioned removing process, each of the trenches 110 has a second width W₂ wider than a width of each opening 108. It is worth noting that, since a portion of each P-type doped diffusion region 114 with relatively high doping concentration can be reacted with oxygen to become the oxide layer 116 and can be removed during the consequent step of removing the oxide layer 116, a surface doping concentration of each P-type doped diffusion region 114 can therefore be reduced effectively. As a result, a concentration distribution of hole carriers and a concentration distribution of electron carriers in the super junction structure can be uniformed, and a voltage sustaining ability of the super junction structure is improved.

As shown in FIG. 8, another deposition process is carried out to form an insulating material layer (not shown), such as silicon oxide, on the hard mask layer 106 and filling up each trench 110. A chemical mechanical polishing (CMP) process is performed to remove the insulating material layer (not shown) on the hard mask layer 106. Another etching process is then performed to remove a portion of the insulating material layer in the openings 108. An insulating layer 118 is therefore formed inside each trench 110. In this embodiment, the upper surface of the insulating layer 118 is approximately leveled with the upper surface of the pad layer 104, but is not limited thereto. That is to say, a level of the upper surface of the insulating layer 118 may be located between a level of the upper surface of the pad layer 104 and a level of the upper surface of the N-type semiconductor substrate 102, or it may be even aligned with the upper surface of the N-type semiconductor substrate 102.

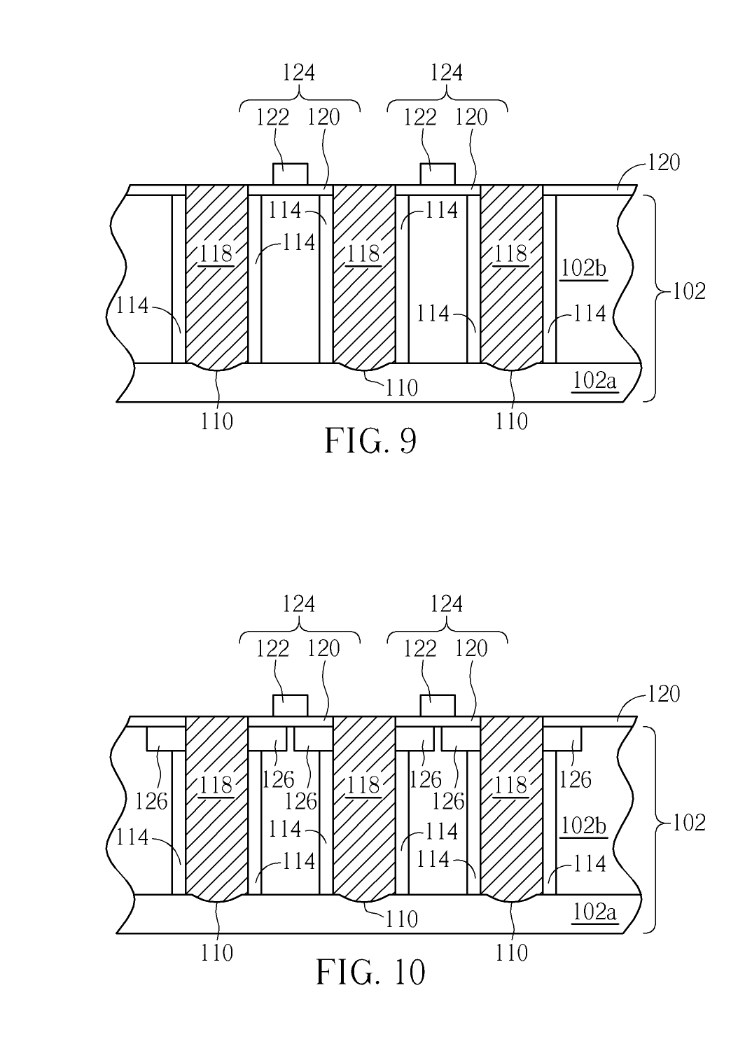

As shown in FIG. 9, the hard mask layer 106 and the pad layer 104 is subsequently removed and the N-type semiconductor substrate 102 is exposed. A gate insulating layer 120 is then formed on the N-type semiconductor substrate 102 by means of another thermal oxidation process. After that, a conductive material layer, such as polysilicon, is formed to cover the gate insulating layer 120 and the insulating layer 118. Another photolithographic process and another etching process are carried out so that the conductive material layer is patterned to form a gate conductive layer 122 on the N-type semiconductor substrate 102 between two adjacent trenches 110, which can serve as a gate of the power transistor device. Besides, a gate structure 124 comprises a gate conductive layer 122 and a gate insulating layer 120, which is disposed between the gate conductive layer 122 and the N-type semiconductor substrate 102. In this embodiment, the upper surface of the gate insulating layer 120 is approximately leveled with the upper surface of the insulating layer 118, but is not limited thereto. In other embodiments of the present invention, there may be only one gate structure, which is located on the N-type semiconductor substrate 102 at one side of one of the trenches 110.

Please refer to FIG. 10. By using the gate conductive layer 122 as a mask, another P-type ion implantation process and another thermal drive-in process are carried out consequently so that two P-type doped base regions 126 are formed in the N-type semiconductor substrate 102 separately at two sides of each gate structure 124. Each of the P-type doped base regions 126 is respectively in contact with each of the P-type doped diffusion regions 114 and partially overlaps each of the gate structures 124, which can function as a base in a power transistor device.

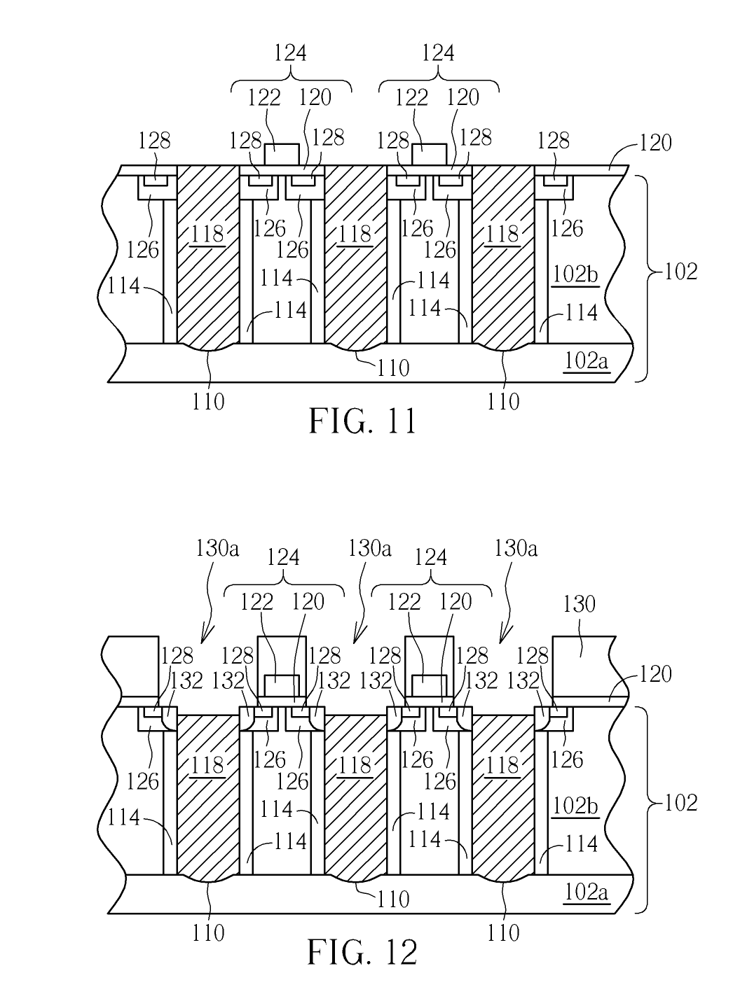

Please refer to FIG. 11. By using a photomask (not shown), another N-type ion implantation process and another thermal drive-in process are carried out consequently. As a result, an N-type doped source region 128 is formed in each of the P-type doped base regions 126 and partially overlaps with each of the gate structures 124, which can function as a source in a power transistor device. The number of the gate structures 124, the P-type doped base regions 126 and the N-type doped source regions 128 are not limited to be more than one, they also may be single structures and regions. The number of which can be adjusted according to particular requirements.

As shown in FIG. 12, a dielectric layer 130, such as silicon oxide, is formed to cover the gate structure 124 and the insulating layer 118. Subsequently, by performing a photolithographic and an etching process, a plurality of contact openings 130a is formed in the dielectric layer 130. And a portion of the gate insulating layer 120 and of the insulating layer 118 exposed from the corresponding contact openings 130a are partially removed. Each contact opening 130a can expose the N-type doped source regions 128 and the P-type doped base regions 126. Another P-type ion implantation and another thermal drive-in process are carried out consequently so that a P-type doped contact region 132 is formed in each of the P-type doped base regions 126.

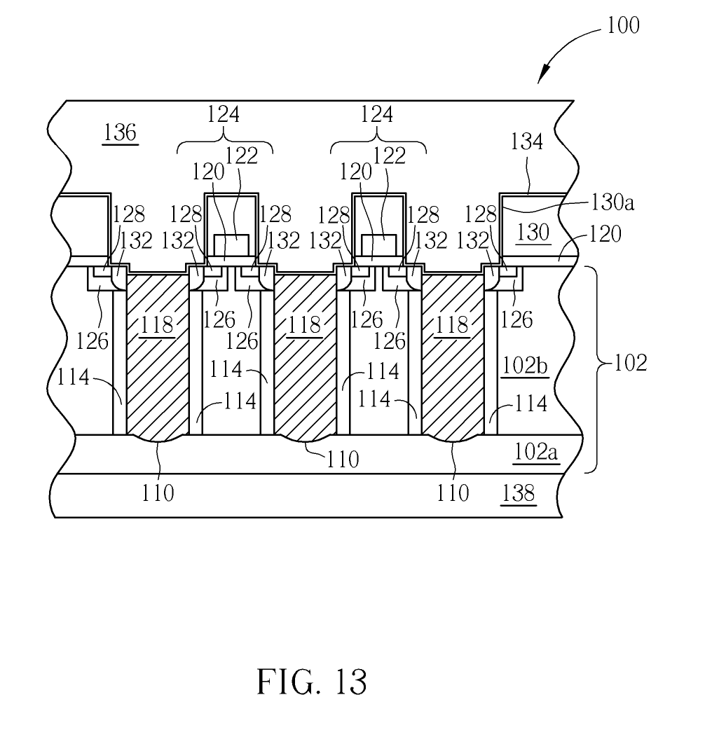

As shown in FIG. 13, another deposition process is carried out to form a barrier layer 134, such as titanium or titanium nitride, on the dielectric layer 130 and on two sidewalls and the bottom of the contact openings 130a. Next, a source metal layer 136 can form on the barrier layer, which fills up each contact openings 130a and covers the dielectric layer 130. A drain metal layer 138 can then be formed on the bottom of the P-type substrate 102. The power transistor device of this embodiment is therefore completed. In this embodiment, steps for forming the source metal layer 136 may include plasma sputter process, electron beam deposition process and so forth, and the source metal layer 136 may include titanium, titanium nitride, aluminum, tungsten, or other metal or metal composite, but is not limited thereto.

It should be noted that a method of manufacturing a super junction structure in a power transistor device is not limited to the above embodiments as various changes and modifications may be made thereto without departing from the scope and the spirit of the present invention. In the following paragraphs, various embodiments or modifications will be further described. Additionally, for the sake of clarity and convenience, the same reference signs are generally used to refer to corresponding or similar features in the following modified and different embodiments.

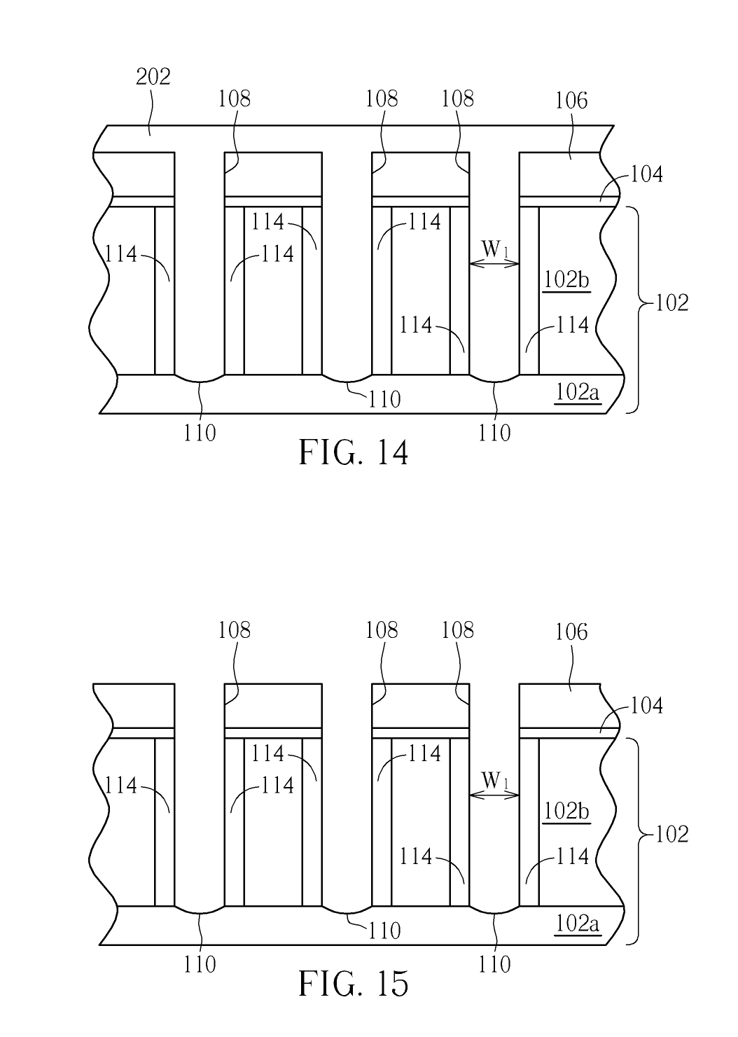

Please refer to FIGS. 14 to 15 accompanied with FIGS. 4 to 7. FIGS. 14 to 15 are schematic, cross-sectional diagrams illustrating a method of manufacturing a super junction structure according to another embodiment of the present invention. Compared to the above embodiment, the fabrication method of this embodiment further provides other steps between the step for removing the dopant source layer and the thermal oxidation process. These steps, for example, include sequentially performing a step for filling another dopant source layer into the trenches, another thermal drive-in process and a step for removing the another dopant source layer at least once. In this way, a doping concentration of the P-type doped diffusion regions can be modified to a required value. In this embodiment, procedures for forming P-type doped diffusion regions are similar to those described in the above embodiment, as shown in FIGS. 4-5. Subsequently, as shown in FIG. 14, the dopant source layer 112 is removed and another the dopant source layer 202 is filled into the trenches 110. In this embodiment, the composition of the dopant source layer 202 is the same as that of the dopant source layer 112 in the previous embodiment, such as borosilicate glass (BSG). And the dopant source layer 202 also includes a plurality of P-type dopants, but is not limited thereto. Subsequently, another thermal drive-in process is performed. During the thermal drive-in process, the P-type dopants can diffuse into the doped diffusion regions 114. Then, the dopant source layer 202 is removed. The subsequent processes of this embodiment are almost the same as in the above embodiment shown in FIGS. 6-7, so their description is therefore omitted for the sake of clarity and convenience. Furthermore, in other embodiments of the invention, in order to modify a doping concentration of the P-type doped diffusion regions 114 to a required value, a series of steps, includes for example a step for filling another dopant source layer 202 into the trenches, another thermal drive-in process and a step for removing the another dopant source layer 202 can be repeated several times, if required.

In other embodiments of the invention, successive steps such as a step for filling another dopant source layer into trenches, another thermal drive-in process, a step for removing the another dopant source layer, another thermal oxidation process and a step for removing an oxide layer, may be repeated several times so that a required doping concentration of the P-type doped diffusion regions and a required super junction structure can be obtained.

To summarize, the present invention provides a thermal oxidation process during processes for manufacturing a super junction structure. By performing the thermal oxidation process, a portion of each doped diffusion region adjacent to each trench can be oxidized into an oxide layer. Since the oxide layer is oxidized from the doped diffusion region with relatively high doping concentration, if the oxide layer is removed by a consequent removing process, a surface doping concentration of the doped diffusion region can therefore be reduced effectively. As a result, a concentration distribution of hole carriers and a concentration distribution of electron carriers in the super junction structure can be uniformed, and a voltage sustaining ability of the super junction structure is hence improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of manufacturing a super junction structure, comprising:
providing a semiconductor substrate having a first conductivity type;
forming at least a trench in the semiconductor substrate;
separately forming two doped diffusion regions in the semiconductor substrate on both sides of the trench, wherein a doping concentration of each of the doped diffusion regions close to a sidewall of the trench is larger than a doping concentration of each of the doped diffusion regions away from the sidewall of the trench, and each of the doped diffusion regions has a second conductivity type different from the first conductivity type;
performing a thermal oxidation process to form an oxide layer on the sidewall of the trench, wherein a part of each of the doped diffusion regions in contact with the sidewall of the trench reacts with oxygen to form a part of the oxide layer; and
removing the oxide layer.

2. The method of manufacturing the super junction structure according to claim 1, wherein the step for forming the doped diffusion regions comprises:
filling the trench with a dopant source layer, wherein the dopant source layer comprises a plurality of dopants having the second conductivity type; and
performing a thermal drive-in process to diffuse the dopants into the semiconductor substrate and form the doped diffusion regions.

3. The method of manufacturing the super junction structure according to claim 2, wherein between a step for forming the doped diffusion regions and a step for performing the thermal oxidation process, the method further comprises removing the dopant source layer.

4. The method of manufacturing the super junction structure according to claim 3, wherein between performing the thermal oxidation process and a step for removing the dopant source layer, the method further comprises sequentially performing a step for filling another dopant source layer, another thermal drive-in process and a step for removing the another dopant source layer at least once.

5. The method of manufacturing the super junction structure according to claim 1, wherein between a step for providing the semiconductor substrate and a step for forming the trench, the method further comprises forming a hard mask layer on the semiconductor substrate having at least an opening.

6. The method of manufacturing the super junction structure according to claim 1, wherein after a step for removing the oxide layer, the trench has a width wider than a width of the opening.

7. The method of manufacturing the super junction structure according to claim 1, wherein a step for removing the oxide layer comprises a wet etch process.

8. The method of manufacturing the super junction structure according to claim 1, wherein a gas applied in the thermal oxidation process comprises steam (H₂O), oxygen (O₂), a mixed gas of hydrogen chloride (HCl) and steam, a mixed gas of hydrogen chloride and oxygen, a mixed gas of nitrogen (N₂) and steam, or a mixed gas of nitrogen and oxygen.

9. The method of manufacturing the super junction structure according to claim 1, wherein a temperature range of the thermal oxidation process ranges from approximately 800° C. to approximately 1200° C.

10. A method of manufacturing a power transistor device, comprising:
providing a semiconductor substrate having a first conductivity type;
forming at least a trench in the semiconductor substrate;
separately forming two doped diffusion regions in the semiconductor substrate on both sides of the trench, wherein a doping concentration of each of the doped diffusion regions close to a sidewall of the trench is larger than a doping concentration of each of the doped diffusion regions away from the sidewall of the trench, and each of the doped diffusion regions has a second conductivity type different from the first conductivity type;
performing a thermal oxidation process to form an oxide layer on the sidewall of the trench, wherein a part of each of the doped diffusion regions in contact with the sidewall of the trench is reacted with oxygen to form a part of the oxide layer;
removing the oxide layer,
forming an insulating layer in the trench;
forming a gate structure on the semiconductor substrate on at least the side of the trench;
separately forming two doped base regions in the semiconductor substrate on both sides of the gate structure, and each of the doped base regions is respectively in contact with each of the doped diffusion regions, wherein the doped base regions have the second conductivity type; and
respectively forming a doped source region in each of the doped base regions.

11. The method of manufacturing the power transistor device according to claim 10, wherein the step for forming the doped diffusion regions comprises:
filling the trench with a dopant source layer, wherein the dopant source layer comprises a plurality of dopants having the second conductivity type; and
performing a thermal drive-in process to diffuse the dopants into the semiconductor substrate and form the doped diffusion regions.

12. The method of manufacturing the power transistor device according to claim 11, wherein between a step for forming the doped diffusion regions and a step for performing the thermal oxidation process, the method further comprises removing the dopant source layer.

13. The method of manufacturing the power transistor device according to claim 12, wherein between performing the thermal oxidation process and a step for removing the dopant source layer, the method further comprises sequentially performing a step of filling another dopant source layer, another thermal drive-in process and a step for removing the another dopant source layer at least once.

14. The method of manufacturing the power transistor device according to claim 10, wherein between a step for providing the semiconductor substrate and a step for forming the trench, the method further comprises forming a hard mask layer on the semiconductor substrate having at least an opening.

15. The method of manufacturing the power transistor device according to claim 14, wherein after a step for removing the oxide layer, the trench has a width wider than a width of the opening.

16. The method of manufacturing the power transistor device according to claim 14, wherein between a step for forming the insulating layer and a step for forming the gate structure, the method further comprises removing the hard mask layer.

17. The method of manufacturing the power transistor device according to claim 10, wherein a step for removing the oxide layer comprises a wet etch process.

18. The method of manufacturing the power transistor device according to claim 10, wherein a gas applied in the thermal oxidation process comprises steam, oxygen, a mixed gas of hydrogen chloride and steam, a mixed gas of hydrogen chloride and oxygen, a mixed gas of nitrogen and steam, or a mixed gas of nitrogen and oxygen.

19. The method of manufacturing the power transistor device according to claim 10, wherein a temperature range of the thermal oxidation process ranges from approximately 800° C. to approximately 1200° C.

20. A method of reducing a surface doping concentration of a doped diffusion region, comprising:
providing a semiconductor substrate having a doped diffusion region disposed therein, and the doped diffusion region being in contact with a surface of the semiconductor substrate, wherein a doping concentration of the doped diffusion region close to the surface is larger than a doping concentration of the doped diffusion region away from the surface;
performing a thermal oxidation process to form an oxide layer on the surface of the semiconductor substrate, wherein a part of the doped diffusion region in contact with the surface is reacted with oxygen to form a part of the oxide layer; and
removing the oxide layer.
